(19) United States
(12) Patent Application Publication
(10) Pub. No.: US 2026/0209400 A1
(43) Pub. Date: Jul. 23, 2026

(54) REACTIVE FLAME RETARDANT CONTAINING BENZOCYCLOBUTENE GROUP-BEARING CYCLOPHOSPHAZENE, AND PREPARATION METHOD AND USE THEREOF

(71) Applicant: WUHAN DESYTEK ENVIRONMENTAL PROTECTION & NEW MATERIALS CO., LTD., Huangshi (CN)

(72) Inventors: WENYONG GUO, Huangshi (CN); BIAO LU, Huangshi (CN)

(73) Assignee: WUHAN DESYTEK ENVIRONMENTAL PROTECTION & NEW MATERIALS CO., LTD., Huangshi (CN)

(21) Appl. No.: 19/567,339

(22) Filed: Mar. 16, 2026

Related U.S. Application Data
(63) Continuation of application No. PCT/CN2025/132598, filed on Nov. 5, 2025.

(30) Foreign Application Priority Data
Nov. 15, 2024 (CN) 202411637541.5

(51) Int. Cl. C08F 8/40; C07F 9/6581; C07F 9/6593; C08J 5/24; H05K 1/03

(52) U.S. Cl. CPC C08F 8/40; C07F 9/65815; C07F 9/65817; C07F 9/65818; C08J 5/24; H05K 1/0366; C08J 2347/00; H05K 2201/012

(57) ABSTRACT

The disclosure relates to the field of flame retardants, in particular, to a reactive flame retardant containing benzocyclobutene group-bearing cyclophosphazene, and a preparation method and use thereof. The disclosure provides a reactive flame retardant containing benzocyclobutene group-bearing cyclophosphazene having a molecular structural formula in which at least one benzocyclobutene group is included on the cyclophosphazene. The preparation method for a reactive flame retardant containing benzocyclobutene group-bearing cyclophosphazene provided by the disclosure, by reacting a hydroxy compound containing at least a hydroxy-BCB derivative with a halocyclophosphazene under the action of an acid scavenger, a reactive flame retardant containing benzocyclobutene group-bearing cyclophosphazene is obtained after a purification treatment. The resin composition using the reactive flame retardant containing benzocyclobutene group-bearing cyclophosphazene, provided by the disclosure, includes the reactive flame retardant containing benzocyclobutene group-bearing cyclophosphazene.

### CROSS-REFERENCE TO RELATED APPLICATIONS

The present application claims the priority of a Chinese patent application with the application number of “CN2024116375415” and entitled “REACTIVE FLAME RETARDANT CONTAINING BENZOCYCLOBUTENE GROUP-BEARING CYCLOPHOSPHAZENE, AND PREPARATION METHOD AND USE THEREOF”, and all the contents of the priority document are incorporated into the present application document as the reference content of the present application document.

### TECHNICAL FIELD

The disclosure relates to the field of flame retardants, in particular, to a reactive flame retardant containing benzocyclobutene group-bearing cyclophosphazene, and a preparation method and use thereof.

### BACKGROUND

With the improvement of environmental protection and human health awareness, the research of new high-efficiency, low-toxicity, halogen-free, and environmentally friendly flame retardants has become a hot spot. Compared with the additive flame retardant, the dispersion of reactive flame retardants is poor, the addition amount is large, and the mechanical properties of the matrix are affected. The reactive flame retardants are well dispersed in the material, the loading amount is small, and there is no intermolecular anisotropy, which has little effect on the mechanical properties of the material. In particular, the reactive flame retardant, which contains a variety of flame retardant elements in the same molecule, has the advantages of high flame retardant efficiency, good charring performance, and so on, so it has a great market application demand. With the development of 5G technology, the copper-clad laminate used for high-frequency and high-speed substrates is developing continuously. According to the high-frequency application conditions and the processing and assembly requirements of PCB, it needs to have a wide range of performance. Among the main characteristics, reducing the dielectric loss (Dk, Df) of high-frequency signals is the most important item.

At present, the most popular reactive flame retardants contain hydroxyl as a reactive group, and the polarity of hydroxyl is large, which is not conducive to the introduction of materials with low dielectric properties. For example, CN109467574A discloses a novel vanillin-based reactive flame retardant containing a hydroxyl in its structure. CN105175777A discloses a phosphorus-nitrogen synergistic reactive flame retardant for polyurethane, the structure of which also contains hydroxyl. These reactive flame retardants cannot meet the dielectric properties of high-performance PCB plates, while hexaphenoxy cyclotriphosphazene can only be used as an additive flame retardant.

Benzocyclobutene (BCB) is an excellent low-dielectric material, but benzocyclobutene is a low-boiling-point volatile liquid, which can not be directly used in high-frequency, high-speed printed circuit board PCB board. Benzocyclobutene was derivatized to prepare reactive flame retardants, which will have a good application prospect.

### SUMMARY

In view of the above, it is an object of the disclosure to provide a reactive flame retardant containing benzocyclobutene group-bearing cyclophosphazene having low DK, Df, and high Tg, as a reactive flame retardant, performing a Diels-Alder addition reaction with an unsaturated olefin monomer, an unsaturated resin, etc. To form a bulk flame retardant material, which can overcome the disadvantages caused by the use of an additive flame retardant in the prior art and is used in a resin material for a high-frequency high-speed copper-clad laminate, and a preparation method and use thereof. In addition, the preparation method for the reactive flame retardant containing benzocyclobutene group-bearing cyclophosphazene is suitable for industrial mass production.

In order to achieve the object of the disclosure, the following technical solutions are provided:

In a first aspect, the disclosure provides a reactive flame retardant containing benzocyclobutene group-bearing cyclophosphazene having the general molecular structural formula of Formula I:

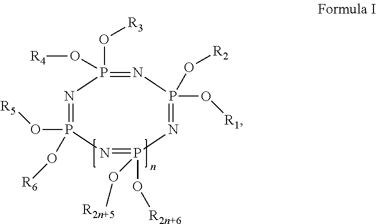

in Formula I, the substituents R₁, R₂, R₃, R₄, R₅, R₆, R₂ₙ₊₅, and R₂ₙ₊₆ include at least one benzocyclobutene group; n is selected from 0, 1, 2, 3, 4, or 5 and represents the number of nitrogen-phosphorus double bonds which may also be increased on the cyclophosphazene. Each of the substituents R₁, R₂, R₃, R₄, R₅, R₆, R₂ₙ₊₅, and R₂ₙ₊₆ may also be independently selected from one of alkyl, alkenyl, and aryl.

Further, in the substituent groups R₁, R₂, R₃, R₄, R₅, R₆, R₂ₙ₊₅, and R₂ₙ₊₆, the number of carbon atoms of the alkyl is an integer from 1 to 30, preferably the number of carbon atoms is not more than 18; the number of carbon atoms of the alkenyl is an integer from 2 to 30, preferably the number of carbon atoms is not more than 12; the number of carbon atoms of the aryl is an integer from 6 to 30.

Preferably, the alkyl includes one of methyl, ethyl, propyl, butyl, pentyl, hexyl, heptyl, octyl, nonyl, dodecyl, hexadecyl, octadecyl; the alkenyl includes one of allyl, alkenylbutyl, alkenylpentyl, alkenylhexyl, alkenylheptyl, alkenyloctyl, alkenylnonyl, alkenyldecyl, and alkenyldodecyl; the aryl includes one of a hydrocarbyl-substituted or unsubstituted phenyl, benzyl, phenethyl, phenylpropyl, phenylbutyl, biphenyl, diphenylmethyl, diphenylethyl, diphenylvinyl, diphenylethenyl, vinylphenyl, allylphenyl, vinylbenzyl, and allylbenzyl;
further, the benzocyclobutene group has the structural formula represented by Formula II:

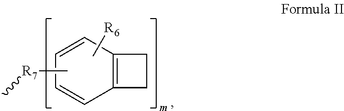

in Formula II, the linking group R₇ is selected from one of a chemical single bond, alkylene, alkenylene, arylene; the substituent R₈ is selected from one of hydrogen, alkyl, alkenyl, aryl; m is an integer from 1 to 100 representing the number of benzocyclobutenyl on the linking group R₇; preferably, m is an integer from 1 to 10; more preferably, m is 1, 2, 3, 4 or 5.
preferably, in the linking group R₇, the number of carbon atoms of the alkylene is an integer of 1 to 30; the number of carbon atoms of the alkenylene is an integer of 2 to 30; the number of carbon atoms of the arylene is an integer from 6 to 30; the number of carbon atoms of the alkyl is an integer from 1 to 30; the number of carbon atoms of the alkenyl is an integer from 2 to 30; the number of carbon atoms of the aryl is an integer of 6 to 30.

More preferably, in the linking group R₇, the alkylene includes one of methylene, ethylene, propylene, butylene, pentylene, hexylene, heptylene, octylene, decylene, cyclohexylene, cyclopentylene, hexadecylene; the alkenylene includes one of ethenylene, propenylene, butenylene, pentenylene, hexenylene, heptenylene, octenylene, decenylene; the arylene includes one of hydrocarbon-substituted or unsubstituted phenylene, benzylidene, styrylidene, biphenylene, biphenylene, biphenylene, and biphenylene having 1 to 18 carbon atoms.

Preferably, in the substituent R₈, the number of carbon atoms of the alkyl is not more than 30, preferably not more than 18; the number of carbon atoms of the alkenyl is not more than 30, preferably not more than 12; the number of carbon atoms of the aryl is not more than 30, preferably not more than 12.

More preferably, in the substituent R₈, the alkyl includes at least one of methyl, ethyl, propyl, butyl, pentyl, hexyl, heptyl, octyl, nonyl, decyl, dodecyl, octadecyl, cyclobutyl annulated with benzocyclobutene; the alkenyl includes one of ethenyl, propenyl, butenyl, pentenyl, hexenyl, heptenyl, octenyl, decenyl, dodecenyl, styryl, vinylstyryl, diphenylethenyl; the aryl includes one of phenyl, methylphenyl, ethylphenyl, benzyl, biphenyl, biphenylmethyl, phenyl which forms a ring with benzocyclobutene, and a benzocyclobutene group which forms a ring with benzocyclobutene.

In a second aspect, the disclosure provides a preparation method for a reactive flame retardant containing benzocyclobutene group-bearing cyclophosphazene for use in preparing a reactive flame retardant containing benzocyclobutene group-bearing cyclophosphazene provided in the first aspect of the disclosure, including the steps of: subjecting a hydroxy compound to a substitution reaction with a halocyclophosphazene in the presence of an organic solvent and an acid scavenger under a dry atmosphere to obtain the reactive flame retardant containing benzocyclobutene group-bearing cyclophosphazene;
wherein the hydroxy compound includes an alcohol and/or a phenol and alkali metal salts thereof, and includes at least a hydroxy-BCB derivative represented by Formula III:

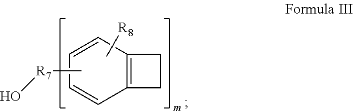

in Formula III, the linking group R₇ is selected from one of a chemical single bond, alkylene, alkenylene, arylene; the substituent R₈ is selected from one of hydrogen, alkyl, alkenyl, aryl; m is an integer from 1 to 100.
wherein a molecular structural formula of the halocyclophosphazene is represented by Formula IV:

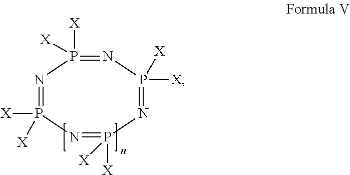

In Formula V, X is a halogen and n is selected from 0, 1, 2, 3, 4, or 5.

Further, the substitution reaction may be performed in a manner including: in a dry atmosphere, an organic solvent, a hydroxy compound, and an acid scavenger are added to a reactor, a halocyclophosphazene is added dropwise, and after the addition is completed, the temperature is raised, and the reaction is maintained at this temperature.

Preferably, the temperature at which the halocyclophosphazene is added dropwise is between room temperature and 60° C.

Further, the reaction step further includes a separation and purification operation after the completion of the substitution reaction to obtain the purified reactive flame retardant containing the benzocyclobutene group-bearing cyclophosphazene.

Preferably, the hydroxy compound and the acid scavenger are completely in an organic solvent, and then the halocyclophosphazene is added dropwise; or further including the step of preparing the alcohol or phenol in the hydroxy compound as an alkali metal salt.

Further, in the halocyclophosphazene, the halogen is selected from at least one of chlorine, bromine, and iodine.

Preferably, the halocyclophosphazene includes at least one of hexachlorocyclotriphosphazene, hexabromocyclotriphosphazene, hexiodocyclotriphosphazene, octachlorocyclotetraphosphazene, octabromocyclotetraphosphazene, octiodocyclotetraphosphazene, decachlorocyclopentaphosphazene, decachlorocyclohexaphosphazene, tetradecachlorocyclheptaphosphazene, and hexadecachlorocycloctaphosphazene.

Further, the dry atmosphere includes at least one dry reaction environment of an inert gas atmosphere and connected with a drying device externally connected with a drying agent; the inert gas includes at least one of nitrogen, argon, or helium; the desiccant includes anhydrous calcium chloride.

Further, the molar ratio of the hydroxyl in the hydroxy compound to the halogen in the halocyclophosphazene is (1.0-1.2):1.0, and the number of moles of hydroxyl in the hydroxy-BCB derivative is at least 1.0 times the number of moles of the halocyclophosphazene.

Further, the hydroxy compound further includes at least one of an aliphatic alcohol having no more than 30 carbon atoms, an alkenyl alcohol having no more than 30 carbon atoms, a phenol having no more than 30 carbon atoms, and an aromatic alcohol having no more than 30 carbon atoms.

Preferably, the hydroxy compound further includes at least one of an aliphatic alcohol having no more than 18 carbon atoms, an alkenyl alcohol having no more than 12 carbon atoms, a phenol having no more than 12 carbon atoms, and an aromatic alcohol having no more than 12 carbon atoms.

More preferably, the hydroxy compound further includes methanol, ethanol, propanol, butanol, pentanol, hexanol, heptanol, octanol, nonanol, dodecanol, hexadecanol, octadecanol, propenol, butenol, pentenol, hexenol, heptenol, octenol, nonenol, decenol, dodecenol, phenol, methylphenol, ethylphenol, benzyl alcohol, biphenol, biphenylmethanol, vinylphenol, allylphenol, vinylbenzyl alcohol, allylbenzyl alcohol, benzenediol, phenylethyl alcohol, phenylpropyl alcohol, phenylbutyl alcohol, ethylene glycol, butenediol, cis-4-cyclopentene-1,3-diol, at least one of pentaerythritol; also included are salts of at least one of the foregoing compounds in the form of sodium alkoxide, potassium alkoxide, sodium phenoxide, and potassium phenoxide.

Further, the organic solvent includes at least one of acetonitrile, chlorobenzene, tetrahydrofuran, DMF, DMI, DMSO, DMAC, NMP, toluene, xylene; the ratio of the amount by volume of the solvent to the mass of the halocyclophosphazene is (2-20):1.

Further, the acid scavenger is at least one of potassium carbonate, sodium carbonate, potassium acetate, triethylamine, diisopropylethyl amine, N-ethyl dicyclohexyl amine, tetramethylguanidine (TMG), 1,4-diazabicyclo[2.2.2]octane (DABCO), potassium hydroxide, sodium hydroxide, cesium hydroxide, sodium hydride, sodium methoxide, sodium tert-butoxide; the molar ratio of the acid scavenger to the halogen in the halocyclophosphazene is (1.0-1.5):1.0; Preferably, the molar ratio of the acid scavenger to the halogen in the halocyclophosphazene is (1.0-1.15):1.0.

Further, the temperature of the isothermal reaction is 60° C.-130° C.; the time for the isothermal reaction is 12-72 h.

Further, one of the methods for performing the product separation and purification includes: cooling the reaction solution to room temperature, sequentially adding an alkaline solution and washing with saturated brine to neutrality, separating the organic phase, concentrating the residue obtained from the organic phase, and subjecting the same to silica gel column chromatography to obtain the reactive flame retardant containing benzocyclobutene group-bearing cyclophosphazene.

Preferably, the alkaline solution includes at least one of a potassium carbonate solution, a potassium bicarbonate solution, a sodium carbonate solution, and a sodium bicarbonate solution.

In a third aspect, the disclosure provides a resin composition including the benzocyclobutene group-bearing cyclophosphazene-reactive flame retardant of the first aspect of the disclosure.

Further, the resin composition further includes at least one of an unsaturated olefin, an unsaturated resin, a benzocyclobutene monomer, and a benzocyclobutene resin.

In a fourth aspect, the disclosure provides a prepreg prepared from the resin composition of the third aspect. a PCB board including the prepreg and a material made therefrom.

Advantageous effects of the disclosure:
(1) The disclosure provides a reactive flame retardant containing benzocyclobutene group-bearing cyclophosphazene, wherein the reactive flame retardant containing benzocyclobutene group-bearing cyclophosphazene has a high phosphorus content, is synergistically flame retardant with nitrogen and phosphorus, and the benzocyclobutene group having an active group in the molecule thereof can perform a Diels-Alder addition reaction with an unsaturated olefin, an unsaturated resin, etc., and the flame retardant does not migrate and does not deteriorate the physical properties of the material due to the addition of the flame retardant. In addition, the reactive flame retardant of the disclosure has the characteristics of good material compatibility and stable performance. Therefore, it has very good application and development prospects.
(2) The disclosure provides a reactive flame retardant containing benzocyclobutene group-bearing cyclophosphazene, which is copolymerized with a monomer or resin containing an unsaturated double bond, a benzocyclobutene monomer, a benzocyclobutene resin, etc. To form a bulk flame retardant material, which has a low DK, Df, and a high Tg, and can be used in a high-frequency high-speed copper-clad resin material to meet the stringent requirements of reducing the dielectric loss of a high-frequency signal.
(3) The preparation method of a reactive flame retardant containing benzocyclobutene group-bearing cyclophosphazene provided by the disclosure is simple in operation, mild in conditions, and easy to obtain raw materials, which is suitable for industrial large-scale production.

### BRIEF DESCRIPTION OF DRAWINGS

FIG. 1 is the HNMR spectrum of the reactive flame retardant containing benzocyclobutene group-bearing cyclophosphazene obtained in Example 1 of the disclosure;

FIG. 2 is the infrared spectrum of the reactive flame retardant containing benzocyclobutene group-bearing cyclophosphazene obtained in Example 1 of the disclosure.

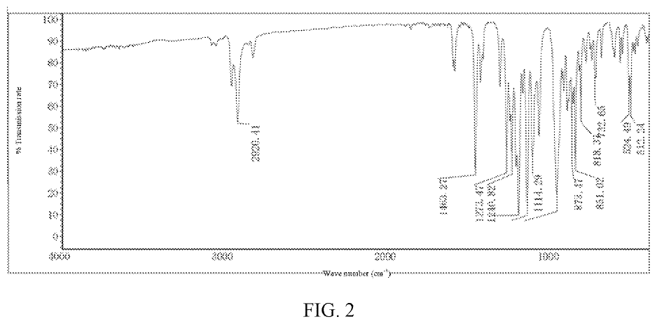

FIG. 3 is the DSC plots of the reactive flame retardant containing benzocyclobutene group-bearing cyclophosphazenes A and C obtained in Example 1 and Example 3, respectively, of the disclosure;

FIG. 4 is the Tg profiles of the reactive flame retardant containing benzocyclobutene group-bearing cyclophosphazenes A and C obtained in Examples 1 and 3, respectively, of the disclosure;

### DETAILED DESCRIPTION OF THE EMBODIMENTS

Mode for the Invention Reference will now be made in detail to the embodiments of the disclosure, examples of which are intended to be illustrative of the disclosure, and examples of which are intended to be illustrative of the scope of the disclosure are not intended to be limited to the examples described below.

According to a first aspect of the disclosure, there is provided a reactive flame retardant containing benzocyclobutene group-bearing cyclophosphazene, which has a general molecular structural formula represented by the following formula:

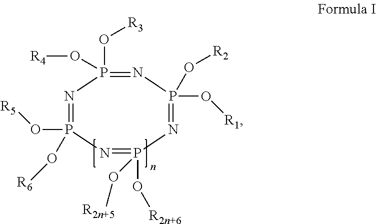

wherein at least one of the substituents R₁, R₂, R₃, R₄, R₅, R₆, R₂ₙ₊₅, and R₂ₙ₊₆ is a benzocyclobutene group; n is selected from 0, 1, 2, 3, 4, or 5 and represents the number of nitrogen-phosphorus double bonds which may also be increased on the cyclophosphazene. Each of the substituents R₁, R₂, R₃, R₄, R₅, R₆, R₂ₙ₊₅, and R₂ₙ₊₆ may also be independently selected from one of alkyl, alkenyl, and aryl.

It should be noted that the benzocyclobutene group includes at least one benzocyclobutene group, and may contain multiple BCB groups to form a benzocyclobutene group, if present, and is not limited to containing only one benzocyclobutene group.

It should be noted that the substituents R₁ and R₂, R₃ and R₄, R₅ and R₆, and R₂ₙ₊₅ and R₂ₙ₊₆ may be relatively independent substituents, and may also be represented by any two or more substituents connected to each other to form a ring, and should not be limited to the independent substituents represented in the structural formula.

It should be noted that, n represents the number of nitrogen-phosphorus double bonds that may also be increased in the cyclophosphazene; when the values of n are 1, 2, 3, 4 and 5 sequentially, 2, 4, 6, 8 and 10 substituents are added sequentially, and the substituents R₂ₙ₊₅ may be specifically represented as R₇, R₉, R₁₁, R₁₃ and R₁₅; R₂ₙ₊₆ may in particular be represented as R₈, R₁₀, R₁₂, R₁₄, and R₁₆. In particular, when n=0, the substituents R₂ₙ₊₅, R₂ₙ₊₆ are absent, meaning that the substituent groups R₁, R₂, R₃, R₄, R₅, R₆ include at least one benzocyclobutene group; when n=1, the substituents R₂ₙ₊₅, R₂ₙ₊₆ represent linking groups R₇, R₈ attached to the oxygen on the increased nitrogen-phosphorus double bond, which may be the same or different from any one of the substituents R₁, R₂, R₃, R₄, R₅, R₆; however, when n is 2, 3, 4 or 5, then the substituents R₂ₙ₊₅, R₂ₙ₊₆ should be understood to be the corresponding addition of 4, 6, 8 or 10 identical or non-identical substituents, including at least one of an alkyl, alkenyl, aryl or benzocyclobutene group, for each addition of one nitrogen-phosphorus double bond, and should not simply be understood to be equivalent to the addition of two substituents for n=1, i. e. representing two identical substituents R₂ₙ₊₅, R₂ₙ₊₆.

It should be noted that the alkyl includes straight or branched chain alkyls, cycloalkyls; the alkenyl includes straight-chain or branched alkenyl, alkenyl-substituted hydrocarbyl; the aryl includes alkyl substituted aryl, aryl substituted alkyl, aryl substituted aryl, a polyaryl group, an alkyl substituted polyaryl group. Unless otherwise specified, each substituent includes any isomer that may exist in any form.

It should be noted that the substituent R₈ represents at least one substituent on the benzocyclobutenyl, and may also be a substituent forming a ring with the BCB group, and is not limited to only one substituent represented in Formula II and Formula III.

Illustratively, the disclosure provides a reactive flame retardant containing benzocyclobutene group-bearing cyclophosphazene, including, but not limited to, compounds represented by the following structural formulas A-R. The compounds listed below are merely exemplary and readily available starting materials, and should not be construed to limit the scope of the disclosure accordingly:

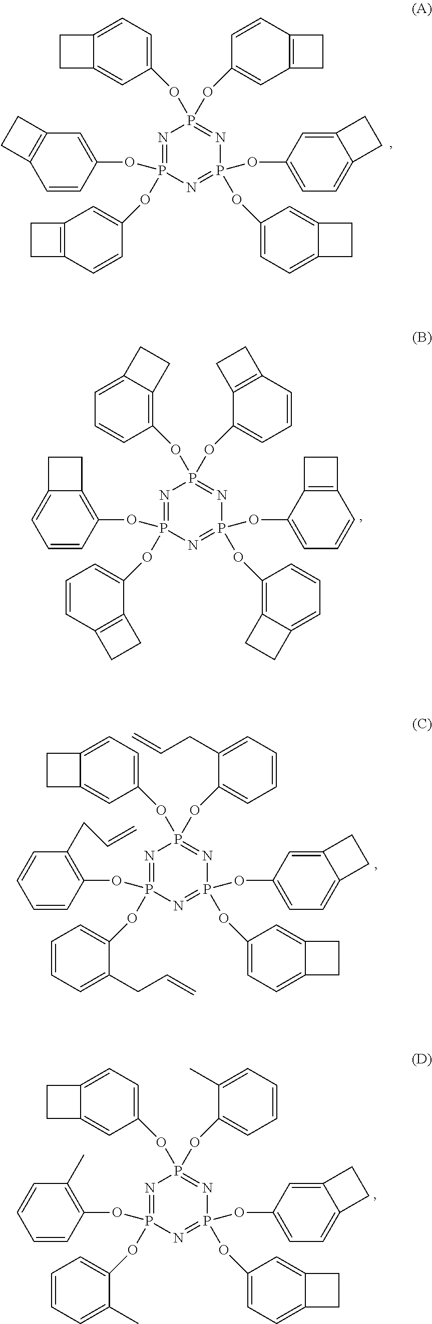 [SMILES: c1cc2c(cc1OP1(Oc3ccc4c(c3)CC4)=NP(Oc3ccc4c(c3)CC4)(Oc3ccc4c(c3)CC4)=NP(Oc3ccc4c(c3)CC4)(Oc3ccc4c(c3)CC4)=N1)CC2 ; c1cc2c(c(OP3(Oc4cccc5c4CC5)=NP(Oc4cccc5c4CC5)(Oc4cccc5c4CC5)=NP(Oc4cccc5c4CC5)(Oc4cccc5c4CC5)=N3)c1)CC2 ; C=CCc1ccccc1OP1(Oc2ccc3c(c2)CC3)=NP(Oc2ccc3c(c2)CC3)(Oc2ccc3c(c2)CC3)=NP(Oc2ccccc2CC=C)(Oc2ccccc2CC=C)=N1 ; Cc1ccccc1OP1(Oc2ccc3c(c2)CC3)=NP(Oc2ccc3c(c2)CC3)(Oc2ccc3c(c2)CC3)=NP(Oc2ccccc2C)(Oc2ccccc2C)=N1]

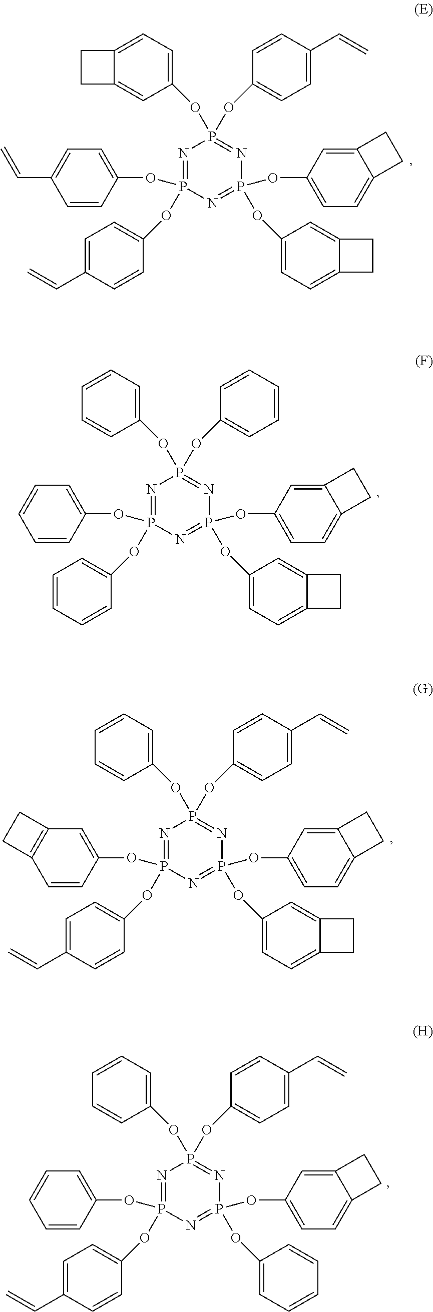 [SMILES: C=Cc1ccc(OP2(Oc3ccc(C=C)cc3)=NP(Oc3ccc(C=C)cc3)(Oc3ccc4c(c3)CC4)=NP(Oc3ccc4c(c3)CC4)(Oc3ccc4c(c3)CC4)=N2)cc1 ; c1ccc(OP2(Oc3ccccc3)=NP(Oc3ccccc3)(Oc3ccccc3)=NP(Oc3ccc4c(c3)CC4)(Oc3ccc4c(c3)CC4)=N2)cc1 ; C=Cc1ccc(OP2(Oc3ccccc3)=NP(Oc3ccc4c(c3)CC4)(Oc3ccc4c(c3)CC4)=NP(Oc3ccc(C=C)cc3)(Oc3ccc4c(c3)CC4)=N2)cc1 ; C=Cc1ccc(OP2(Oc3ccccc3)=NP(Oc3ccccc3)(Oc3ccc(C=C)cc3)=NP(Oc3ccccc3)(Oc3ccc4c(c3)CC4)=N2)cc1]

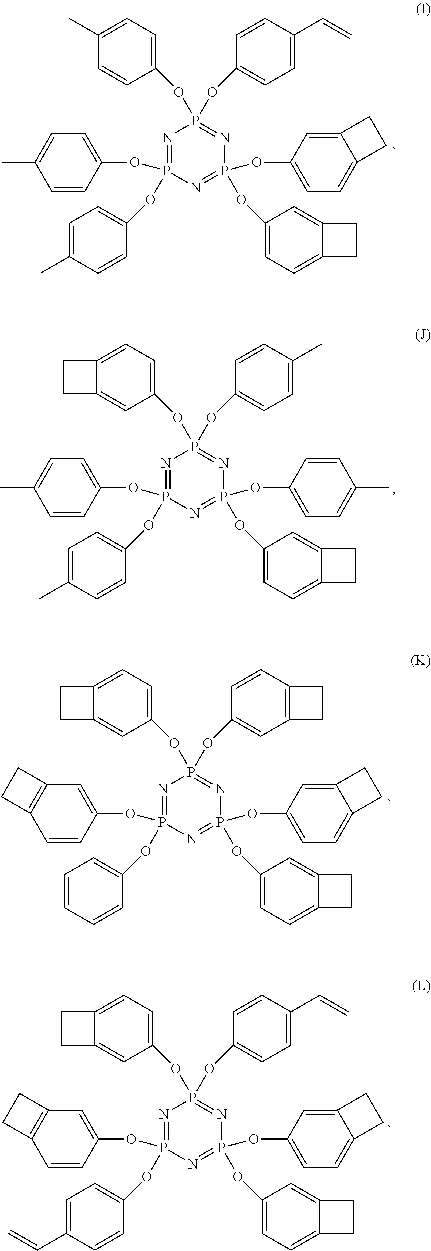

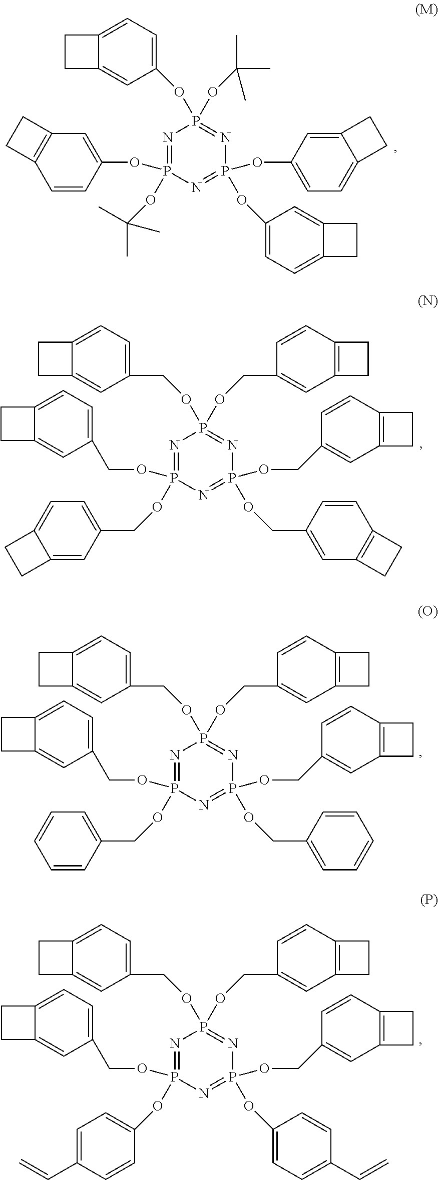 [SMILES: CC(C)(C)OP1(Oc2ccc3c(c2)CC3)=NP(Oc2ccc3c(c2)CC3)(Oc2ccc3c(c2)CC3)=NP(Oc2ccc3c(c2)CC3)(OC(C)(C)C)=N1 ; c1cc2c(cc1COP1(OCc3ccc4c(c3)CC4)=NP(OCc3ccc4c(c3)CC4)(OCc3ccc4c(c3)CC4)=NP(OCc3ccc4c(c3)CC4)(OCc3ccc4c(c3)CC4)=N1)CC2 ; c1ccc(COP2(OCc3ccc4c(c3)CC4)=NP(OCc3ccccc3)(OCc3ccc4c(c3)CC4)=NP(OCc3ccc4c(c3)CC4)(OCc3ccc4c(c3)CC4)=N2)cc1 ; C=Cc1ccc(OP2(OCc3ccc4c(c3)CC4)=NP(OCc3ccc4c(c3)CC4)(OCc3ccc4c(c3)CC4)=NP(OCc3ccc4c(c3)CC4)(Oc3ccc(C=C)cc3)=N2)cc1]

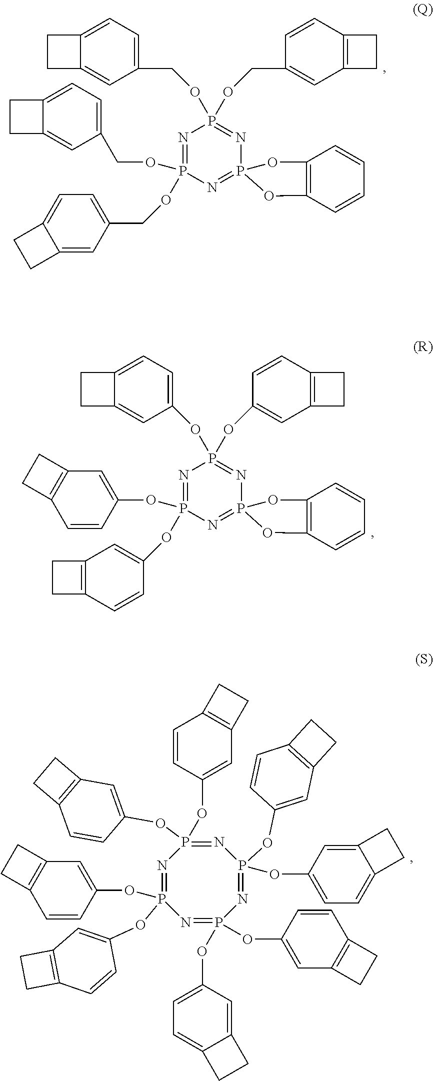 [SMILES: c1ccc2c(c1)OP1(=NP(OCc3ccc4c(c3)CC4)(OCc3ccc4c(c3)CC4)=NP(OCc3ccc4c(c3)CC4)(OCc3ccc4c(c3)CC4)=N1)O2 ; c1ccc2c(c1)OP1(=NP(Oc3ccc4c(c3)CC4)(Oc3ccc4c(c3)CC4)=NP(Oc3ccc4c(c3)CC4)(Oc3ccc4c(c3)CC4)=N1)O2 ; c1cc2c(cc1OP1(Oc3ccc4c(c3)CC4)=NP(Oc3ccc4c(c3)CC4)(Oc3ccc4c(c3)CC4)=NP(Oc3ccc4c(c3)CC4)(Oc3ccc4c(c3)CC4)=NP(Oc3ccc4c(c3)CC4)(Oc3ccc4c(c3)CC4)=N1)CC2]

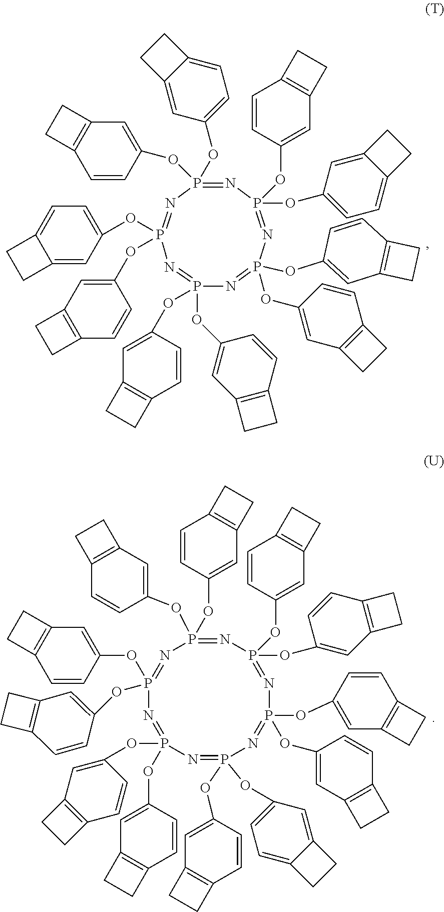 [SMILES: c1cc2c(cc1OP1(Oc3ccc4c(c3)CC4)=NP(Oc3ccc4c(c3)CC4)(Oc3ccc4c(c3)CC4)=NP(Oc3ccc4c(c3)CC4)(Oc3ccc4c(c3)CC4)=NP(Oc3ccc4c(c3)CC4)(Oc3ccc4c(c3)CC4)=NP(Oc3ccc4c(c3)CC4)(Oc3ccc4c(c3)CC4)=N1)CC2 ; c1cc2c(cc1OP1(Oc3ccc4c(c3)CC4)=NP(Oc3ccc4c(c3)CC4)(Oc3ccc4c(c3)CC4)=NP(Oc3ccc4c(c3)CC4)(Oc3ccc4c(c3)CC4)=NP(Oc3ccc4c(c3)CC4)(Oc3ccc4c(c3)CC4)=NP(Oc3ccc4c(c3)CC4)(Oc3ccc4c(c3)CC4)=NP(Oc3ccc4c(c3)CC4)(Oc3ccc4c(c3)CC4)=N1)CC2]

In a second aspect, the disclosure provides a process for preparing a reactive flame retardant containing benzocyclobutene group-bearing cyclophosphazene for use in preparing a reactive flame retardant containing benzocyclobutene group-bearing cyclophosphazene according to the first aspect of the disclosure, the reaction step including:

Adding an organic solvent, a hydroxy compound, and an acid scavenger into a reactor under a dry atmosphere, adding a halocyclophosphazene dropwise at an appropriate temperature, after the addition is completed, raising the temperature and maintaining the reaction at this temperature, and then performing separation and purification to obtain the purified reactive flame retardant containing the benzocyclobutene group-bearing cyclophosphazene.

In the disclosure, in order to increase the reactivity of the hydroxy compound, the hydroxy compound may be further reacted with halocyclophosphazene in the form of an alkali metal salt prepared by reacting the hydroxyl with an alkali metal hydroxide or the like. The use of a hydroxy compound as a raw material and an alkali metal salt of the hydroxy compound falls within the scope of protection of the preparation method for the reactive flame retardant containing benzocyclobutene group-bearing cyclophosphazene described in the disclosure.

Reference will now be made in detail to specific examples.

### Example 1

In a reactor equipped with a stirrer, a thermometer, a reflux condenser and connected with a drying device, 60 g of chlorobenzene, 22.3 g (0.185 mol) of 4-hydroxy BCB and 18.8 g (0.186 mol) of triethylamine were added, stirred, and the temperature was raised to 50° C. and maintained; a solution of 9.73 g (0.028 mol) of hexachlorocyclotriphosphazene in 10 g of chlorobenzene was initially added dropwise, after the addition was completed, the temperature was raised to 110° C. and the reaction was maintained at this temperature for 24 h; after cooling to room temperature, the reaction solution was sequentially washed with sodium carbonate solution and saturated brine. The organic phase was separated, washed to neutral pH, and concentrated. The residue was purified by silica gel column chromatography, and the eluate was concentrated and dried to obtain 21.4 g of solid with a yield of 90.0%, namely the reactive flame retardant containing benzocyclobutene group-bearing cyclophosphazene, with molecular structural formula represented by Formula (A).

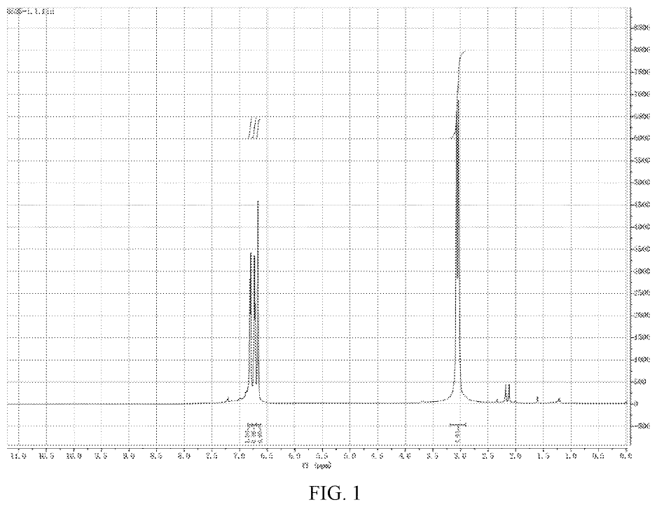

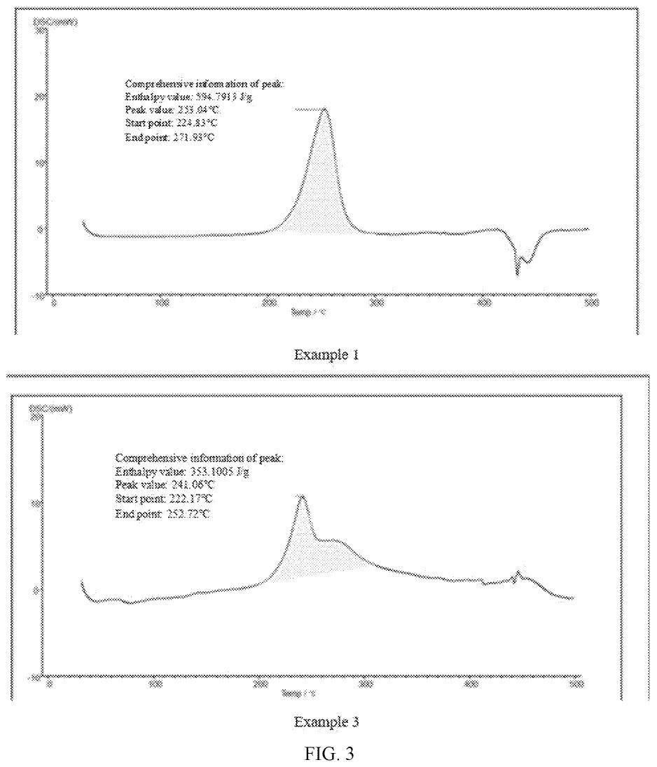

The HNMR spectrum for the product of this example is shown in FIG. 1, data: δ 2.93-3.11 (d, 24H), 6.75 (s, 6H), 6.79-6.82 (dd, 6H), 6.87-6.93 (d, 6H); the infrared spectrum of the product of this example is shown in FIG. 3. From the spectra and data analysis, the molecular structural formula of compound A can be confirmed.

### Example 2

In a reactor equipped with a stirrer, a thermometer, a reflux condenser and connected with a drying device, 110 g of toluene was added as a solvent, followed by 22.3 g (0.185 mol) of 3-hydroxy BCB and 10.4 g (0.186 mol) of potassium hydroxide, the temperature was raised to the reflux of toluene, and water was taken out by a water separator. After reaction for 2 h, under a nitrogen atmosphere, the temperature was lowered to 40° C. and maintained at this temperature, and a solution of 9.73 g (0.028 mol) of hexachlorocyclotriphosphazene in 10 g of toluene was initially added dropwise. After the addition was completed, the temperature was raised to the reflux of toluene, and the reaction was maintained at this temperature for 15 h; after cooling to room temperature, the reaction solution was sequentially washed with sodium carbonate solution and saturated brine. The organic phase was separated, washed to neutral pH, and concentrated. The residue was purified by silica gel column chromatography, and the eluate was concentrated and dried to obtain 16.2 g of a light-yellow solid with a yield of about 68%, namely the reactive flame retardant containing benzocyclobutene group-bearing cyclophosphazene, with molecular structural formula represented by Formula (B).

The HNMR data for the product of this example is: δ 3.01-3.13 (d, 24H), 7.10-7.13 (d, 6H), 7.16-7.19 (dd, 6H), 7.25-7.29 (m, 6H).

### Example 3

In a reactor equipped with a stirrer, a thermometer, a reflux condenser and connected with a drying device, 100 g of tetrahydrofuran was added as a solvent, followed by 10.55 g (0.088 mol) of 4-hydroxy BCB, 11.81 g (0.088 mol) of o-allylphenol and 18.8 g (0.186 mol) of triethylamine, the temperature was raised to 45° C. and maintained at this temperature, and a solution of 9.73 g (0.028 mol) of hexachlorocyclotriphosphazene in 15 g of tetrahydrofuran was initially added dropwise, after the addition was completed, the temperature was raised to reflux and the reaction was maintained at this temperature for 72 h; after cooling to room temperature, the insoluble was filtered, the filtrate was sequentially washed with sodium carbonate solution and saturated brine. The organic phase was separated, washed to neutral pH, and concentrated. The residue was purified by silica gel column chromatography, and the eluate was concentrated and dried to obtain 19.45 g of a light-yellow solid with a yield of 78%, namely the reactive flame retardant containing benzocyclobutene group-bearing cyclophosphazene. The molecular structural formula of the flame retardant is represented by Formula C.

The HNMR data for the product of this example is: δ 2.92-3.16 (d, 12H), 3.25 (s, 6H), 4.82-4.95 (dd, 3H), 5.92-6.12 (m, 6H), 6.85 (s, 3H), 6.91-7.03 (m, 6H), 7.16-7.25 (m, 12H).

### Example 4

In a reactor equipped with a stirrer, a thermometer, a reflux condenser and connected with a drying device, 60 g of chlorobenzene was added as a solvent, followed by 10.55 g (0.088 mol) of 4-hydroxy BCB and 18.8 g (0.186 mol) of triethylamine, the temperature was raised to 50° C. and maintained, 9.73 g (0.028 mol) of hexachlorocyclotriphosphazene (dissolved in 10 g of the solvent) was initially added dropwise, after the addition was completed, the temperature was raised to the reflux of the solvent, and the reaction was maintained at this temperature 12 h, then a solution of 9.52 g (0.088 mol) of o-methylphenol in 15 g of chlorobenzene was added dropwise, and the reaction was maintained at this temperature for another 12 h; after cooling to room temperature at the end of the reaction, the reaction solution was sequentially washed with sodium carbonate solution and brine. The organic phase was separated, washed to neutral pH, and concentrated. The residue was purified by silica gel column chromatography, and the eluate was concentrated and dried to obtain 19.35 g of solid with a yield of 85%, namely the reactive flame retardant containing benzocyclobutene group-bearing cyclophosphazene. The molecular structural formula of the flame retardant is represented by Formula D.

The HNMR data for the product of this example is: δ 2.19 (s, 9H), 2.91-3.17 (d, 12H), 6.85 (s, 3H), 6.96-7.13 (m, 6H), 7.19-7.28 (m, 12H).

### Example 5

In a reactor equipped with a stirrer, a thermometer, a reflux condenser and connected with a drying device, 60 g of chlorobenzene was added as a solvent, followed by 10.81 g (0.09 mol) of 4-hydroxy BCB and 18.8 g (0.186 mol) of triethylamine, the temperature was raised to 50° C. and maintained; a solution of 9.73 g (0.028 mol) of hexachlorocyclotriphosphazene in 15 g of chlorobenzene was initially added dropwise, after the addition was completed, the temperature was raised to the reflux of the solvent, and the reaction was maintained at this temperature for 10 h; then a solution of 10.81 g (0.09 mol) of p-hydroxystyrene in 15 g of chlorobenzene was added dropwise, and the reaction was maintained at this temperature for another 10 h; after cooling to room temperature at the end of the reaction, the reaction solution was sequentially washed with sodium carbonate solution and brine. The organic phase was separated, washed to neutral pH, and concentrated. The residue was purified by silica gel column chromatography, and the eluate was concentrated and dried to obtain 19.5 g of solid with a yield of 82%, namely the reactive flame retardant containing benzocyclobutene group-bearing cyclophosphazene. The molecular structural formula of the flame retardant is represented by Formula E.

The HNMR data for the product of this example is: δ 2.90-3.14 (d, 12H), 5.38 (d, 3H), 5.96-6.08 (m, 6H), 6.85 (s, 3H), 6.91-7.03 (m, 6H), 7.16-7.25 (m, 12H).

### Example 6

In a reactor equipped with a stirrer, a thermometer, a reflux condenser and connected with a drying device, 60 g of chlorobenzene was added as a solvent, followed by 6.97 g (0.058 mol) of 4-hydroxy BCB and 24.9 g (0.18 mol) of potassium carbonate, the temperature was raised to 50° C. and maintained; a solution of 9.73 g (0.028 mol) of hexachlorocyclotriphosphazene in 15 g of chlorobenzene was initially added dropwise, after the addition was completed, the temperature was raised to the reflux of the solvent, and the reaction was maintained at this temperature for 10 h; then a solution of 11.19 g (0.12 mol) of phenol in 15 g of chlorobenzene was added dropwise, and the reaction was maintained at this temperature for another 10 h; after cooling to room temperature at the end of the reaction, the reaction solution was sequentially washed with sodium carbonate solution and saturated brine. The organic phase was separated, washed to neutral pH, and concentrated. The residue was purified by silica gel column chromatography, and the eluate was concentrated and dried to obtain 16.3 g of solid with a yield of 78%, namely the reactive flame retardant containing benzocyclobutene group-bearing cyclophosphazene. The molecular structural formula of the flame retardant is represented by Formula F.

### Example 7

In a reactor equipped with a stirrer, a thermometer, a reflux condenser and connected with a drying device, 100 g of tetrahydrofuran was added as a solvent, followed by 10.55 g (0.088 mol) of 4-hydroxy BCB and 24.8 g (0.18 mol) of potassium carbonate, the temperature was raised to 50° C. and maintained, and a solution of 9.73 g (0.028 mol) of hexachlorocyclotriphosphazene dissolved in 15 g of tetrahydrofuran was initially added dropwise, after the addition was completed, the temperature was raised to 65° C. and the reaction was maintained at this temperature 10 h. Then a solution of 6.93 g (0.058 mol) of p-hydroxystyrene dissolved in 15 g of tetrahydrofuran was added dropwise, and the reaction was maintained at this temperature for another 10 h; then a solution of 2.82 g (0.03 mol) of phenol dissolved in 15 g of tetrahydrofuran was dropped, and the reaction was maintained at this temperature for another 40 h; after cooling to room temperature at the end of the reaction, the reaction solution was sequentially washed with sodium carbonate solution and saturated brine. The organic phase was separated, washed to neutral pH, and concentrated. The residue was purified by silica gel column chromatography, and the eluate was concentrated and dried to obtain 17.3 g of solid with a yield of 75%, namely the reactive flame retardant containing benzocyclobutene group-bearing cyclophosphazene. The molecular structural formula of the flame retardant is represented by Formula G.

### Example 8

In a reactor equipped with a stirrer, a thermometer, a reflux condenser and connected with a drying device, 100 g of tetrahydrofuran was added as a solvent, followed by 3.6 g (0.03 mol) of 4-hydroxy BCB and 24.8 g (0.18 mol) of potassium carbonate, the temperature was raised to 50° C. and maintained, and a solution of 9.73 g (0.028 mol) of hexachlorocyclotriphosphazene dissolved in 15 g of tetrahydrofuran solvent was initially added dropwise, after the addition was completed, the temperature was raised to 65° C. and the reaction is maintained for 10 h. A solution of 8.3 g (0.088 mol) of phenol dissolved in 15 g of tetrahydrofuran solvent was added dropwise, and the reaction was maintained at this temperature for another 10 h; a solution of 7.27 g (0.06 mol) of p-hydroxystyrene dissolved in 15 g of tetrahydrofuran solvent was added dropwise, and the reaction was maintained at this temperature for another 40 h; after cooling to room temperature at the end of the reaction, the reaction solution was sequentially washed with sodium carbonate solution and saturated brine. The organic phase was separated, washed to neutral pH, and concentrated. The residue was purified by silica gel column chromatography, and the eluate was concentrated and dried to obtain 17.6 g of a yellow viscous liquid with a yield of 81.5%, namely the reactive flame retardant containing benzocyclobutene group-bearing cyclophosphazene. The molecular structural formula of the flame retardant is represented by Formula H.

### Example 9

In a reactor equipped with a stirrer, a thermometer, a reflux condenser and connected with a drying device, 100 g of tetrahydrofuran was added as a solvent, followed by 7.0 g (0.058 mol) of 4-hydroxy BCB and 24.84 g (0.18 mol) of potassium carbonate, the temperature was raised to 50° C. and maintained, and a solution of 9.73 g (0.028 mol) of hexachlorocyclotriphosphazene dissolved in 15 g of tetrahydrofuran solvent was initially added dropwise, after the addition was completed, the temperature was raised to 65° C. and the reaction is maintained for 10 h. A solution of 9.54 g (0.088 mol) of p-methylphenol dissolved in 15 g of tetrahydrofuran solvent was added dropwise, and the reaction was maintained at this temperature for another 10 h; a solution of 3.6 g (0.03 mol) of p-hydroxystyrene dissolved in 15 g of tetrahydrofuran solvent was added dropwise, and the reaction was maintained at this temperature for another 40 h; after cooling to room temperature at the end of the reaction, the reaction solution was sequentially washed with sodium carbonate solution and saturated brine. The organic phase was separated, washed to neutral pH, and concentrated. The residue was purified by silica gel column chromatography, and the eluate was concentrated and dried to obtain 18.1 g of solid with a yield of 79.5%, namely the reactive flame retardant containing benzocyclobutene group-bearing cyclotriphosphazene cyclophosphazene. The molecular structural formula of the flame retardant is shown as I.

### Example 10

In a reactor equipped with a stirrer, a thermometer, a reflux condenser and connected with a drying device, 100 g of tetrahydrofuran was added as a solvent, followed by 6.72 g (0.056 mol) of 4-hydroxy BCB and 24.8 g (0.18 mol) of potassium carbonate, the temperature was raised to 50° C. and maintained isothermally, and a solution of 9.73 g (0.028 mol) of hexachlorocyclotriphosphazene dissolved in 15 g of tetrahydrofuran solvent was initially added dropwise, after the addition was completed, the temperature was raised to 65° C. and maintained for a reaction for 20 h, then a solution of 12.1 g (0.112 mol) of p-methylphenol dissolved in 15 g of tetrahydrofuran solvent was dropwise added, and the reaction was maintained at this temperature for another 20 h; after cooling to room temperature at the end of the reaction, the reaction solution was sequentially washed with sodium carbonate solution and saturated brine. The organic phase was separated, washed to neutral pH, and concentrated. The residue was purified by silica gel column chromatography, and the eluate was concentrated and dried to obtain 17.5 g of solid with a yield of 78%, namely the reactive flame retardant containing benzocyclobutene group-bearing cyclophosphazene. The molecular structural formula of the flame retardant is represented by Formula J.

### Example 11

In a reactor equipped with a stirrer, a thermometer, a reflux condenser and connected with a drying device, 100 g of tetrahydrofuran was added as a solvent, followed by 17.66 g (0.147 mol) of 4-hydroxy BCB and 24.8 g (0.18 mol) of potassium carbonate, the temperature was raised to 50° C. and maintained at this temperature, and a solution of 9.73 g (0.028 mol) of hexachlorocyclotriphosphazene dissolved in 15 g of tetrahydrofuran solvent was initially added dropwise, after the addition was completed, the temperature was raised to 65° C. and maintained for a reaction for 10 h, then a solution of 2.88 g (0.03 mol) of phenol was dropwise added, and the reaction was maintained at this temperature for another 10 h; after cooling to room temperature at the end of the reaction, the reaction solution was sequentially washed with sodium carbonate solution and saturated brine. The organic phase was separated, washed to neutral pH, and concentrated. The residue was purified by silica gel column chromatography, and the eluate was concentrated and dried to obtain 18.9 g of a light-yellow solid with a yield of 82%, namely the reactive flame retardant containing benzocyclobutene group-bearing cyclophosphazene. The molecular structural formula of the flame retardant is represented by Formula K.

### Example 12

In a reactor equipped with a stirrer, a thermometer, a reflux condenser and connected with a drying device, 100 g of tetrahydrofuran was added as a solvent, followed by 14.0 g (0.116 mol) of 4-hydroxy BCB and 24.8 g (0.18 mol) of potassium carbonate, the temperature was raised to 50° C. and maintained at this temperature, and a solution of 9.73 g (0.028 mol) of hexachlorocyclotriphosphazene in 15 g of tetrahydrofuran solvent was dropwise added, after the addition was completed, the temperature was raised to 65° C. and maintained for a reaction for 20 h, then a solution of 7.0 g (0.058 mol) of p-hydroxystyrene dissolved in 20 g of tetrahydrofuran solvent was initially added dropwise, and the reaction was maintained at this temperature for another 20 h; after cooling to room temperature at the end of the reaction, the reaction solution was sequentially washed with sodium carbonate solution and saturated brine. The organic phase was separated, washed to neutral pH, and concentrated. The residue was purified by silica gel column chromatography, and the eluate was concentrated and dried to obtain 19.7 g of solid with a yield of 83%, namely the reactive flame retardant containing benzocyclobutene group-bearing cyclophosphazene. The molecular structural formula of the flame retardant is represented by Formula L.

### Example 13

In a reactor equipped with a stirrer, a thermometer, a reflux condenser and connected with a drying device, 100 g of tetrahydrofuran was added as a solvent, followed by 14.26 g (0.118 mol) of 4-hydroxy BCB and 18.2 g (0.18 mol) of triethylamine, the temperature was raised to 50° C. and maintained at this temperature, a solution of 9.73 g (0.028 mol) of hexachlorocyclotriphosphazene dissolved in 15 g of tetrahydrofuran solvent was initially added dropwise, after the addition was completed, the temperature was raised to 65° C. and the reaction was maintained at this temperature for 20 h, then 6.6 g (0.058 mol) of potassium tert-butoxide was added, and the reaction was maintained at this temperature for another 20 h; after cooling to room temperature at the end of the reaction, the reaction solution was sequentially washed with sodium carbonate solution and saturated brine. The organic phase was separated, washed to neutral pH, and concentrated. The residue was purified by silica gel column chromatography, and the eluate was concentrated and dried to obtain 17.4 g of a yellow viscous liquid with a yield of 82%, namely the reactive flame retardant containing benzocyclobutene group-bearing cyclophosphazene. The molecular structural formula of the flame retardant is represented by Formula M.

### Example 14

In a reactor equipped with a stirrer, a thermometer, a reflux condenser and connected with a drying device, 100 g of tetrahydrofuran was added as a solvent, followed by 24.15 g (0.18 mol) of 4-hydroxymethyl BCB and 19.2 g (0.19 mol) of triethylamine, the temperature was raised to 50° C. and maintained at this temperature, a solution of 9.73 g (0.028 mol) of hexachlorocyclotriphosphazene dissolved in 15 g of tetrahydrofuran solvent was initially added dropwise, after the addition was completed, the temperature was raised to 65° C. and the reaction was maintained at this temperature for 40 h; after cooling to room temperature at the end of the reaction, the reaction solution was sequentially washed with sodium carbonate solution and saturated brine. The organic phase was separated, washed to neutral pH, and concentrated. The residue was purified by silica gel column chromatography, and the eluate was concentrated and dried to obtain 23.4 g of a light-yellow solid with a yield of 78%, namely the reactive flame retardant containing benzocyclobutene group-bearing cyclophosphazene. The molecular structural formula of the flame retardant is represented by Formula N.

### Example 15

Under the protection of nitrogen, in a reactor equipped with a stirrer, a thermometer, a reflux condenser and connected with a drying device, 100 g of tetrahydrofuran was added as a solvent, followed by 15.78 g (0.12 mol) of 4-hydroxymethyl BCB and 19.2 g (0.19 mol) of triethylamine, the temperature was raised to 50° C. and maintained at this temperature, a solution of 9.73 g (0.028 mol) of hexachlorocyclotriphosphazene dissolved in 15 g of tetrahydrofuran solvent was initially added dropwise, after the addition was completed, the temperature was raised to 65° C. and the reaction was maintained at this temperature for 20 h, then 6.36 g (0.058 mol) of benzyl alcohol was added, and the reaction was maintained at this temperature for another 20 h; after cooling to room temperature at the end of the reaction, the reaction solution was sequentially washed with sodium carbonate solution and saturated brine. The organic phase was separated, washed to neutral pH, and concentrated. The residue was purified by silica gel column chromatography, and the eluate was concentrated and dried to obtain 18.5 g of a light-yellow solid with a yield of 75%, namely the reactive flame retardant containing benzocyclobutene group-bearing cyclophosphazene. The molecular structural formula of the flame retardant is represented by Formula O.

### Example 16

Under the protection of nitrogen, in a reactor equipped with a stirrer, a thermometer, a reflux condenser and connected with a drying device, 100 g of tetrahydrofuran was added as a solvent, followed by 15.78 g (0.12 mol) of 4-hydroxymethyl BCB and 19.2 g (0.19 mol) of triethylamine, the temperature was raised to 50° C. and maintained at this temperature, a solution of 9.73 g (0.028 mol) of hexachlorocyclotriphosphazene dissolved in 15 g of tetrahydrofuran solvent was initially added dropwise, after the addition was completed, the temperature was raised to 65° C. and the reaction was maintained at this temperature for 20 h, then 6.96 g (0.058 mol) of p-hydroxystyrene was added, and the reaction was maintained at this temperature for another 20 h; after cooling to room temperature at the end of the reaction, the reaction solution was sequentially washed with sodium carbonate solution and saturated brine. The organic phase was separated, washed to neutral pH, and concentrated. The residue was purified by silica gel column chromatography, and the eluate was concentrated and dried to obtain 19.7 g of a light-yellow solid with a yield of 78%, namely the reactive flame retardant containing benzocyclobutene group-bearing cyclophosphazene. The molecular structural formula of the flame retardant is represented by Formula P.

### Example 17

Under the protection of nitrogen, in a reactor equipped with a stirrer, a thermometer, a reflux condenser and connected with a drying device, 100 g of tetrahydrofuran was added as a solvent, followed by 3.30 g (0.03 mol) of catechol and 19.2 g (0.19 mol) of triethylamine, the temperature was raised to 50° C. and maintained at this temperature, a solution of 9.73 g (0.028 mol) of hexachlorocyclotriphosphazene dissolved in 15 g of tetrahydrofuran solvent was initially added dropwise, after the addition was completed, the temperature was raised to 65° C. and the reaction was maintained at this temperature for 20 h, then 15.78 g (0.12 mol) of 4-hydroxymethyl BCB was added, and the reaction was maintained at this temperature for another 20 h; after cooling to room temperature at the end of the reaction, the reaction solution was sequentially washed with sodium carbonate solution and saturated brine. The organic phase was separated, washed to neutral pH, and concentrated. The residue was purified by silica gel column chromatography, and the eluate was concentrated and dried to obtain 16.7 g of a light-yellow solid with a yield of 77%, namely the reactive flame retardant containing benzocyclobutene group-bearing cyclophosphazene. The molecular structural formula of the flame retardant is represented by Formula Q.

### Example 18

Under the protection of nitrogen, in a reactor equipped with a stirrer, a thermometer, a reflux condenser and connected with a drying device, 100 g of tetrahydrofuran as a solvent, 3.30 g (0.03 mol) of catechol and 19.2 g (0.19 mol) of triethylamine were added, the temperature was raised to 50° C. and maintained at this temperature, a solution of 9.73 g (0.028 mol) of hexachlorocyclotriphosphazene dissolved in 15 g of tetrahydrofuran solvent was initially added dropwise, after the addition was completed, the temperature was raised to 65° C. and the reaction was maintained at this temperature for 20 h, then 14.42 g (0.12 mol) of 4-hydroxy BCB was added, and the reaction was maintained at this temperature for another 30 h; after cooling to room temperature at the end of the reaction, the reaction solution was sequentially washed with sodium carbonate solution and saturated brine. The organic phase was separated, washed to neutral pH, and concentrated. The residue was purified by silica gel column chromatography, and the eluate was concentrated and dried to obtain 15.3 g of a light-yellow solid with a yield of 76%, namely the reactive flame retardant containing benzocyclobutene group-bearing cyclophosphazene. The molecular structural formula of the flame retardant is represented by Formula R.

### Example 19

A solution of 28.0 g (0.23 mol) of 4-hydroxy BCB, 24.28 g (0.24 mol) of triethylamine, 120 g of chlorobenzene, 12.98 g (0.028 mol) of octachlorocyclotetraphosphazene in 20 g of chlorobenzene under nitrogen was prepared using the same reaction conditions and work-up procedure as described in Example 1 to obtain 25.4 g of product in 80% yield; the reactive flame retardant containing benzocyclobutene group-bearing cyclophosphazene having the molecular structural formula represented by the Formula (S).

### Example 20

A solution of 35.3 g (0.29 mol) of 4-hydroxy BCB, 30.3 g (0.3 mol) of triethylamine, 150 g of chlorobenzene, 14.26 g (0.028 mol) of decachlorocyclopentaphosphazene in 25 g of chlorobenzene under a nitrogen atmosphere was prepared using the same reaction conditions and work-up procedure as described in Example 1 to obtain 30.9 g of product in 78% yield; the reactive flame retardant containing benzocyclobutene group-bearing cyclophosphazene having a molecular structural formula represented by the Formula (T).

### Example 21

A solution of 19.46 g (0.028 mol) of dodecachlorocyclophosphazene in 35 g of chlorobenzene under a nitrogen atmosphere was prepared with 41.2 g (0.34 mol) of 4-hydroxymethyl BCB, 35.4 g (0.38 mol) of triethylamine, 180 g of chlorobenzene using the same reaction conditions and work-up procedure as described in Example 1 to give 38.5 g of the reactive flame retardant containing benzocyclobutene group-bearing cyclophosphazene having a molecular structural formula represented by Formula (U) in a yield of 81%.

### Use Performance Example

The reactive flame retardant containing benzocyclobutene group-bearing cyclophosphazenes prepared in Examples 1-21, respectively, were thermally cured at 230-250° C. for 30 min−1 h to prepare cured films, and the results of Tg measurement were shown in Table 1.

The reactive flame retardant containing benzocyclobutene group-bearing cyclophosphazene prepared in Examples 1 to 21 was subjected to a phosphorus content test using an indirect method test-phosphomolybdenum yellow colorimetric method for quantitative analysis of phosphorus, and a UV-530 ultraviolet-visible spectrophotometer (Shimadzu, Japan) instrument. The results of the phosphorus content test according to the method were shown in Table 1.

Further, the reactive flame retardant containing benzocyclobutene group-bearing cyclophosphazene prepared in Examples 1 to 21 was mixed with an olefinic bond-containing benzocyclobutene resin prepared in CN202211699345.1 of the present company in an amount of 1:10 parts by mass and thermally cured at 160-260° C. to prepare a cured film. The dielectric constant Dk and the dielectric loss tangent Df were measured at a frequency of 10 GHz, and the measured results were shown in Table 1.

TABLE 1
Table of results of various performance
tests on the products of the examples

| | | Phosphorus | Dielectric | Dielectric |
|---|---|---|---|---|
| | Tg(° C.) | content (%) | constant Dk | loss Df |
| Example 1 | 391 | 10.93 | 2.33 | 0.00058 |
| Example 2 | 390 | 10.93 | 2.33 | 0.00059 |
| Example 3 | 387 | 10.42 | 2.35 | 0.00061 |
| Example 4 | 388 | 11.42 | 2.36 | 0.00063 |
| Example 5 | 387 | 10.93 | 2.35 | 0.00062 |
| Example 6 | 392 | 12.46 | 2.36 | 0.00065 |
| Example 7 | 390 | 11.28 | 2.35 | 0.00064 |
| Example 8 | 389 | 12.04 | 2.36 | 0.00066 |
| Example 9 | 388 | 11.42 | 2.36 | 0.00065 |
| Example 10 | 390 | 11.59 | 2.36 | 0.00068 |
| Example 11 | 391 | 11.28 | 2.33 | 0.00059 |
| Example 12 | 390 | 10.93 | 2.33 | 0.00060 |
| Example 13 | 385 | 12.26 | 2.36 | 0.00067 |
| Example 14 | 390 | 9.95 | 2.34 | 0.00060 |
| Example 15 | 391 | 10.54 | 2.35 | 0.00063 |
| Example 16 | 389 | 10.26 | 2.34 | 0.00063 |
| Example 17 | 391 | 11.98 | 2.34 | 0.00060 |
| Example 18 | 392 | 12.91 | 2.33 | 0.00059 |
| Example 19 | 393 | 10.93 | 2.33 | 0.00059 |
| Example 20 | 395 | 10.93 | 2.33 | 0.00059 |
| Example 21 | 396 | 10.93 | 2.33 | 0.00060 |

From the data in Table 1, the phosphorus content test results of the benzocyclobutene group-bearing cyclophosphazene-based reactive flame retardants prepared in Examples 1 to 21 correspond to the phosphorus content of the theoretical structure.

The DSC plots of the products of Example 1 and Example 3 are shown in FIG. 3:

As shown in the DSC plots of FIG. 3: 220-270° C. is the exothermic peak of benzocyclobutene four-membered ring, and the peak value is 250° C. The higher the enthalpy value, the more a four-membered ring is introduced into the unit compound. The benzocyclobutene group-bearing cyclophosphazene compound can undergo Diels-Alder addition with an unsaturated double bond-containing monomer or resin by heating to 220-270° C. to form a bulk flame retardant material. A partial structure of the schematic mechanism diagram is shown as follows:

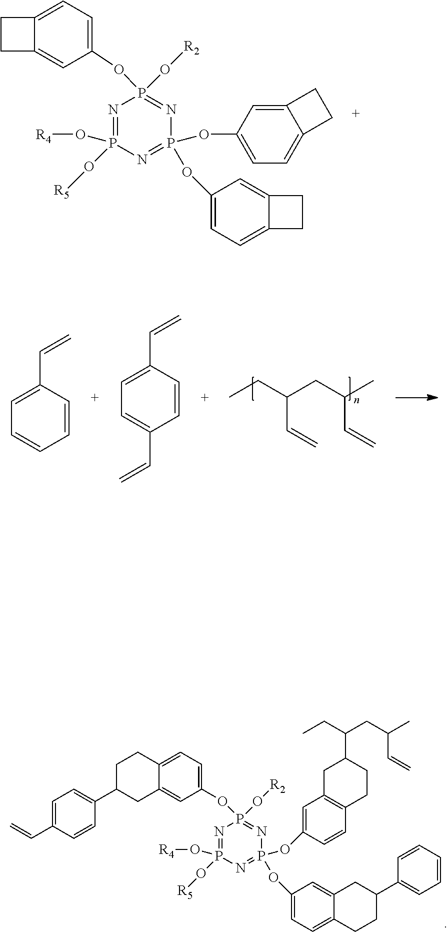

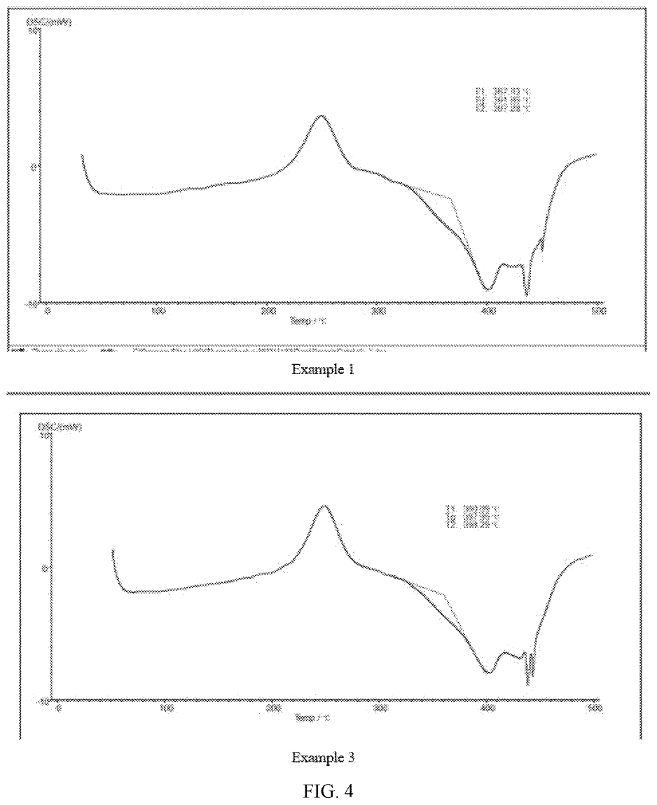

A graph of the Tg testis shown in FIG. 4, which shows the Tg of the flame retardants of Example 1 and Example 3, respectively, in the material.

In order to investigate the flame retardant effect of the flame retardant of the disclosure, a reactive flame retardant containing benzocyclobutene group-bearing cyclophosphazene prepared in Examples 1 to 21 was added to an unsaturated hydrocarbon resin at a mass ratio of 1:10, oxygen was produced, limiting oxygen index (LOI), vertical burning property and heat resistance were tested according to GB2406-93 and UL-94 standard, and the results are shown in Table 2 below:

TABLE 2
Effect of reactive flame retardant containing
benzocyclobutene group-bearing cyclophosphazene
on flame retardancy of hydrocarbon resin

| | Flame | | Nitrogen 5% | limiting | |
|---|---|---|---|---|---|
| | retardant/ | Resin/ | weight loss | oxygen | |
| | in parts | in parts | temperature | index | UL-94 |
| Serial No. | by mass | by mass | (° C.) | (LOI) | (3.2 mm) |
| Example 1 | 15 | 100 | 427 | 28 | V1 |
| Example 1 | 16 | 100 | 425 | 30 | V0 |
| Example 1 | 20 | 100 | 427 | 31.5 | V0 |
| Example 2 | 20 | 100 | 425 | 30 | V0 |
| Example 3 | 20 | 100 | 428 | 31.5 | V0 |
| Example 4 | 20 | 100 | 426 | 31 | V0 |
| Example 5 | 20 | 100 | 420 | 30.8 | V0 |
| Example 6 | 20 | 100 | 419 | 31.5 | V0 |
| Example 7 | 20 | 100 | 421 | 31 | V0 |
| Example 8 | 20 | 100 | 422 | 30.5 | V0 |
| Example 9 | 20 | 100 | 422 | 30.5 | V0 |
| Example 10 | 20 | 100 | 425 | 31 | V0 |
| Example 11 | 20 | 100 | 425 | 31 | V0 |
| Example 12 | 20 | 100 | 425 | 30.5 | V0 |
| Example 13 | 20 | 100 | 418 | 29 | V0 |
| Example 14 | 20 | 100 | 426 | 31.5 | V0 |
| Example 15 | 20 | 100 | 424 | 31 | V0 |
| Example 16 | 20 | 100 | 425 | 30.5 | V0 |
| Example 17 | 20 | 100 | 426 | 30 | V0 |
| Example 18 | 20 | 100 | 428 | 31 | V0 |
| Example 19 | 20 | 100 | 426 | 31 | V0 |
| Example 20 | 20 | 100 | 425 | 30.5 | V0 |
| Example 21 | 20 | 100 | 425 | 30.5 | V0 |

It can be seen from the above table that the reactive flame retardant containing benzocyclobutene group-bearing cyclophosphazene synthesized by the disclosure has good flame retardancy in 100 parts of unsaturated hydrocarbon resin, and when the addition amount exceeds 16 parts, the limiting oxygen index is greatly improved, and the vertical burning test shows that the flame retardant grade can reach UL-94 V0 grade, which shows highly effective flame retardant performance.

In a third aspect, the disclosure provides a resin composition including at least the benzocyclobutene group-bearing cyclophosphazene-reactive flame retardant of the first aspect of the disclosure.

Further, one or a combination of an unsaturated monomer, an unsaturated resin, a benzocyclobutene monomer, and a benzocyclobutene resin is also included in the resin composition. An unsaturated monomer, an unsaturated bond in an unsaturated resin, and an olefinic bond in the reactive flame retardant containing benzocyclobutene group-bearing cyclophosphazene can be polymerized into a high polymer of a crosslinked structure under the action of an initiator; Or ring-opening polymerization of an unsaturated bond in an unsaturated resin and a cyclobutyl group in a BCB group contained in the reactive flame retardant containing benzocyclobutene group-bearing cyclophosphazene into a high polymer of a crosslinked structure under high heat conditions.

Further, the resin composition further includes at least one of a thermal initiator, a crosslinking agent, and an inorganic filler.

Preferably, the resin composition includes the following raw materials in parts by weight:
unsaturated monomers and/or resins: 0 to 60 parts by weight;
benzocyclobutene monomer and/or resin: 0 to 60 parts by weight;
the reactive flame retardant containing benzocyclobutene group-bearing cyclophosphazene: 5-40 parts by weight;
thermal initiators: 0-10 parts by weight;
crosslinking agent: 0-15 parts by weight;
inorganic fillers: 10-60 parts by weight.

The unsaturated monomer includes at least one of styrene, allylbenzene, alkenylhexylbenzene, divinylbenzene, butadiene, pentadiene, hexadiene, heptadiene, octadiene, nonadiene, decadiene, diphenylethylene, vinylbiphenyl, divinylbiphenyl, or vinylbenzocyclobutene.

The unsaturated resin includes at least one of a polybutadiene resin, a polyisoprene resin, a polybutadiene-styrene resin, a polybutadiene-divinylbenzene resin, a polydivinylbenzene resin, a polyisoprene-styrene resin, a polybutadiene-styrene-divinylbenzene resin, a polyisoprene-divinylbenzene resin, a polyisoprene-styrene-divinylbenzene resin.

The benzocyclobutene monomer includes an alkyl, alkenyl, aryl, silane, silyl ether derivative substituted with at least one benzocyclobutene; For example, vinyl benzocyclobutene, benzocyclobutene monomers such as mono-BCB or di-BCB substituted alkyl, alkenyl, aryl derivatives, and the like, and DVS-BCB and the like.

The benzocyclobutene resin includes a polymer having a benzocyclobutene group on a branch chain; Can be a polymer of an alkenyl benzocyclobutene derivative, or can be a benzocyclobutene-modified polymer; For example: BCB resins obtained by polymerizing monomers such as vinylbenzocyclobutene, bisbenzocyclobutenyl ethylene, bisbenzocyclobutenyl decadiene, bisbenzocyclobutenyl divinylbenzene, DVS-BCB; also included are benzocyclobutene resins such as benzocyclobutene-modified polybutadiene resins, polyisoprene resins, polybutadiene-styrene resins, polybutadiene-divinylbenzene resins, polydivinylbenzene resins, polyisoprene-styrene resins, polybutadiene-styrene-divinylbenzene resins, polyisoprene-divinylbenzene resins, polyisoprene-styrene-divinylbenzene resins, and the like. For example, a benzocyclobutene resin containing an olefinic bond prepared in the invention patent CN202211699345.1.

In a fourth aspect, the disclosure provides a prepreg prepared from the resin composition of the third aspect. Specifically, a sol liquid having a xylene solid content of 50% to 75% was prepared in terms of parts by weight of each component in the resin composition, the sol liquid was injected into an impregnation tank under a nitrogen atmosphere, a glass fiber glass fiber fabric (e. g. L-fiber glass cloth of specification 2116) was impregnated into the impregnation tank, the resin composition was attached to the glass fiber cloth, and heating was performed at 150° C. to 260° C. to a semi-cured state to obtain a prepreg. a PCB board including the prepreg and a material made therefrom.

The above-described examples are merely representative of several embodiments of the disclosure, which are described in more detail and detail, and are not to be construed as limiting the scope of the disclosure. It should be noted that a person skilled in the art would have been able to make several variations and modifications without departing from the spirit of the disclosure, and these are all within the scope of the disclosure. Accordingly, the protection sought herein is as set forth in the claims below.

What is claimed is:

1. A reactive flame retardant containing benzocyclobutene group-bearing cyclophosphazene, wherein a general molecular structural formula is represented by Formula I: 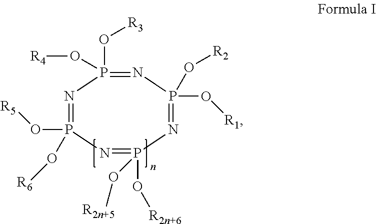
in Formula I, substituents R₁, R₂, R₃, R₄, R₅, R₆, R₂ₙ₊₅, and R₂ₙ₊₆ comprise at least one benzocyclobutene group; n is selected from 0, 1, 2, 3, 4, or 5.

2. The reactive flame retardant containing benzocyclobutene group-bearing cyclophosphazene according to claim 1, wherein each of the substituents R₁, R₂, R₃, R₄, R₅, R₆, R₂ₙ₊₅, and R₂ₙ₊₆ may also be independently selected from one of alkyl, alkenyl, and aryl.

3. The reactive flame retardant containing benzocyclobutene group-bearing cyclophosphazene according to claim 2, wherein the number of carbon atoms of the alkyl is not more than 30; preferably, the number of carbon atoms of the alkyl is not more than 18; the number of carbon atoms of the alkenyl is not more than 30; preferably, the number of carbon atoms of the alkenyl is not more than 12; the number of carbon atoms of the aryl is not more than 30.

4. The reactive flame retardant containing benzocyclobutene group-bearing cyclophosphazene according to claim 1, wherein a molecular structural formula of the benzocyclobutene group is represented by Formula II: 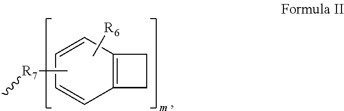
in Formula II, linking group R₇ is selected from one of a chemical single bond, alkylene, alkenylene, arylene; substituent R₈ is selected from one of hydrogen, alkyl, alkenyl, aryl; m is an integer from 1 to 100.

5. The reactive flame retardant containing benzocyclobutene group-bearing cyclophosphazene according to claim 4, wherein in the linking group R₇, the number of carbon atoms of the alkylene is not more than 30, preferably not more than 18; the number of carbon atoms of the alkenylene is not more than 30, preferably not more than 12; the number of carbon atoms of the arylene is not more than 30, preferably not more than 12;
in the substituent R₈, the number of carbon atoms of the alkyl is not more than 30, preferably not more than 18; the number of carbon atoms of the alkenyl is not more than 30, preferably not more than 12; the number of carbon atoms of the aryl is not more than 30, preferably not more than 12;
the m is an integer from 1 to 10; more preferably, m is 1, 2, 3, 4, or 5.

6. A preparation method for the reactive flame retardant containing benzocyclobutene group-bearing cyclophosphazene according to claim 1, wherein the reaction step comprises: subjecting a hydroxy compound to a substitution reaction with a halocyclophosphazene in the presence of an organic solvent and an acid scavenger under a dry atmosphere to obtain the reactive flame retardant containing benzocyclobutene group-bearing cyclophosphazene;
wherein the hydroxy compound comprises an alcohol and/or a phenol and alkali metal salts thereof, and comprises at least a hydroxy-BCB derivative represented by Formula III: 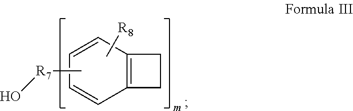
in Formula III, the linking group R₇ is selected from one of a chemical single bond, alkylene, alkenylene, arylene; the substituent R₈ is selected from one of hydrogen, alkyl, alkenyl, aryl; m is an integer from 1 to 100;
wherein a molecular structural formula of the halocyclophosphazene is represented by Formula V: 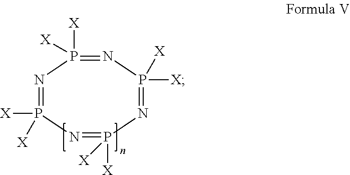
in Formula V, X is a halogen; n is selected from 0, 1, 2, 3, 4, or 5.

7. The preparation method for the reactive flame retardant containing benzocyclobutene group-bearing cyclophosphazene according to claim 6, wherein the molar ratio of the hydroxyl in the hydroxy compound to the halogen in the halocyclophosphazene is (1.0-1.2):1.0, and the number of moles of hydroxyl in the hydroxy-BCB derivative is at least 1.0 times the number of moles of the halocyclophosphazene; and/or,
the hydroxy compound further comprises at least one of an aliphatic alcohol having no more than 30 carbon atoms, an alkenyl alcohol having no more than 30 carbon atoms, a phenol having no more than 30 carbon atoms, and an aromatic alcohol having no more than 30 carbon atoms; preferably, the hydroxy compound further comprises at least one of an aliphatic alcohol having no more than 18 carbon atoms, an alkenyl alcohol having no more than 12 carbon atoms, a phenol having no more than 12 carbon atoms, and an aromatic alcohol having no more than 12 carbon atoms; and/or,
a separation and purification operation after the completion of the substitution reaction is further comprised in the reaction step to obtain the purified reactive flame retardant containing the benzocyclobutene group-bearing cyclophosphazene.

8. A resin composition, comprising the reactive flame retardant containing the benzocyclobutene group-bearing cyclophosphazene according to claim 1.

9. The resin composition according to claim 8, further comprising at least one of an unsaturated resin, a benzocyclobutene monomer, and a benzocyclobutene resin.

10. A prepreg, prepared by thermally curing the resin composition according to claim 8; a PCB board comprising the prepreg and a material made therefrom.
